(19) United States
(12) Patent Application Publication
(10) Pub. No.: US 2022/0301976 A1
(43) Pub. Date: Sep. 22, 2022

(54) CHIP PACKAGING DEVICE AND CORRESPONDING MANUFACTURING METHOD

(71) Applicant: STMicroelectronics (Grenoble 2) SAS, Grenoble (FR)

(72) Inventor: David AUCHERE, Meylan (FR)

(73) Assignee: STMicroelectronics (Grenoble 2) SAS, Grenoble (FR)

(21) Appl. No.: 17/698,749

(22) Filed: Mar. 18, 2022

(30) Foreign Application Priority Data
Mar. 22, 2021 (FR) 2102818

(51) Int. Cl. H01L 23/42; H01L 23/00; H01L 21/52

(52) U.S. Cl. CPC H01L 23/42; H01L 23/562; H01L 21/52

(57) ABSTRACT

Electronic device comprising an electronic chip, a support substrate and a protection cover, the substrate and the cover being assembled so as to form a cavity housing the chip, at least one port equipped with a unidirectional valve being provided in the substrate or the cover, and making it possible to evacuate gas from the inside of the cavity to the outside of the cavity.

### PRIORITY CLAIM

This application claims the priority benefit of French Application for Patent No. 2102818, filed on Mar. 22, 2021, the content of which is hereby incorporated by reference in its entirety to the maximum extent allowable by law.

### TECHNICAL FIELD

Embodiments and implementations relate to the field of microelectronics and, more particularly, to the field of packaging electronic devices comprising electronic chips.

### BACKGROUND

The conventional packaging of an electronic device may comprise an electronic chip attached on an interconnection substrate and covered by a protection cover. The surface of the substrate is, for example, covered by a resin solder mask protecting a metal electrical network.

The cover is typically attached on the resin solder mask.

The cover and the substrate form a sealed cavity housing the chip and intended to protect the chip from impacts and external pollution, particularly liquid pollution and dust coming from the process for manufacturing the packaging.

During heat treatment phases subsequent to the formation of the sealed cavity, for example during polymer curing steps, the sealed cavity may heat up and as a result the gas enclosed inside may increase in pressure.

This pressure increase applies a mechanical stress on the cover, particularly at the attachment with the substrate, which may result in the detachment of the cover, typically via the bursting of the solder mask.

Known solutions for this problem exist, such as providing a through hole in the cover or the substrate in order to evacuate possible overpressures. An alternative solution also exists in locally eliminating the solder mask at the place of contact between the cover and the substrate in order to solidify the attachment.

Nevertheless, such solutions have drawbacks, in particular on the one hand a cavity having a through hole does not make it possible to protect against pollutants, and on the other hand an overpressure of the solder mask between the cover and the substrate forces the electrical network located at the surface of the substrate, under the solder mask, to not be disposed between the cover and the substrate at the place where the solder mask is removed.

Therefore, there is a need for a solution making it possible to avoid the overpressures in the cavity formed by assembling the cover and the substrate, guaranteeing a protection against external pollution, and not introducing supplementary stress on the assembling, such as a stress in the architecture of the electrical network of the substrate.

### SUMMARY

In an embodiment, an electronic device comprises: an electronic chip, a support substrate and a protection cover, the substrate and the cover being assembled so as to form a cavity housing the chip, at least one port equipped with a unidirectional valve being provided in the substrate or the cover, and making it possible to evacuate gas from the inside of the cavity to the outside of the cavity.

Thus, an overpressure of fluid, typically a gas, inside the cavity may circulate through the port to the outside of the cavity, such as to limit the mechanical stress applied between the cover and the substrate. Therefore, the port or ports particularly make it possible to avoid damage of the device due to an overpressure.

In addition, each port is equipped with a unidirectional valve only allowing material to pass through in a single direction, which is towards the outside of the cavity, which makes it possible to guarantee the isolation of the cavity in relation to pollutants outside of the cavity.

Moreover, each port equipped with a valve is provided in the cover or the substrate, this makes it possible to attach the cover on a portion of the substrate able to be covered with a solder resin layer, portion whereon may be disposed a metal connection network.

According to one embodiment, said at least one port is integrated into the substrate and said valve comprises a fixed portion bonded on an outer face of the substrate, located at the edge of said at least one port.

Thus, such an embodiment has advantages in terms of manufacturing cost, because the valve may, for example, be bonded on a standard substrate manufactured upstream of the bonding.

According to one embodiment, said at least one port is integrated into the substrate and the substrate comprises a superposition of dielectric layers, two of the superposed dielectric layers wedging between them a fixed portion of said valve.

Thus, wedging the fixed portion of the valve between the two layers of the substrate makes it possible to improve the mechanical resistance, because the valve and the substrate are secure.

According to one embodiment, said at least one port is integrated into the protection cover, and said valve comprises a fixed portion including branches nesting in the cover.

Thus, the branches of the fixed portion of the valve make it possible to secure the valve and the cover. In particular, if the cover is molded, a material intended to form the cover may creep between the branches of the fixed portion during the molding process.

According to one embodiment, said valve is formed integrally in a flexible material, including a fixed portion integral with an outer face of the substrate or of the cover at the edge of the port, and a free portion facing the port adapted to seal the port by an elastic return force pressing on said outer face.

Thus, the flexible material makes it possible via its elasticity to optimize particularly the sealing provided by the valve.

According to another aspect, it is proposed a method for manufacturing an electronic device comprising: supplying an electronic chip, a support substrate and a cover; forming, in the substrate or in the cover, at least one port equipped with a unidirectional valve; mounting the chip with the substrate; and assembling the substrate and the cover forming a cavity housing the chip, such that said at least one port equipped with said valve makes it possible to evacuate gas from the inside of the cavity to the outside of the cavity.

According to one implementation, the formation in the substrate of at least one port equipped with a unidirectional valve comprises, after supplying the substrate, bonding a fixed portion of said valve on an outer face of the substrate at the edge of said at least one port.

According to one implementation, the formation in the substrate of at least one port equipped with a unidirectional valve is included with manufacture of the substrate comprises, prior to supplying the substrate, bonding two dielectric layers belonging to a superposition of dielectric layers and wedging a fixed portion of said valve.

According to one implementation, the formation in the cover of at least one port equipped with a unidirectional valve is included with manufacture of the cover comprises, prior to supplying the protection cover, molding the cover comprising nesting in the cover the branches of a fixed portion of said valve.

According to one implementation, the formation of said at least one port equipped with a valve comprises forming the valve integrally in a flexible material, securing a fixed portion of the valve on an outer face of the substrate or of the cover at the edge of port, and positioning a free portion of the valve facing the port and adapted to seal the port by an elastic return force pressing on said outer face.

### BRIEF DESCRIPTION OF THE DRAWINGS

Other advantages and features of the invention will become apparent upon examination of the following detailed description of non-limiting embodiments and implementations, and of the appended drawings, wherein:

FIG. 1 illustrates a cross-section of an electronic device;

FIG. 2 illustrates a method for manufacturing the electronic device described in relation with FIG. 1;

FIGS. 3, 4 and 5 illustrate the formation of a single port equipped with one valve; and

FIG. 6 illustrates a pumping system adapted for the circulation of a fluid.

### DETAILED DESCRIPTION

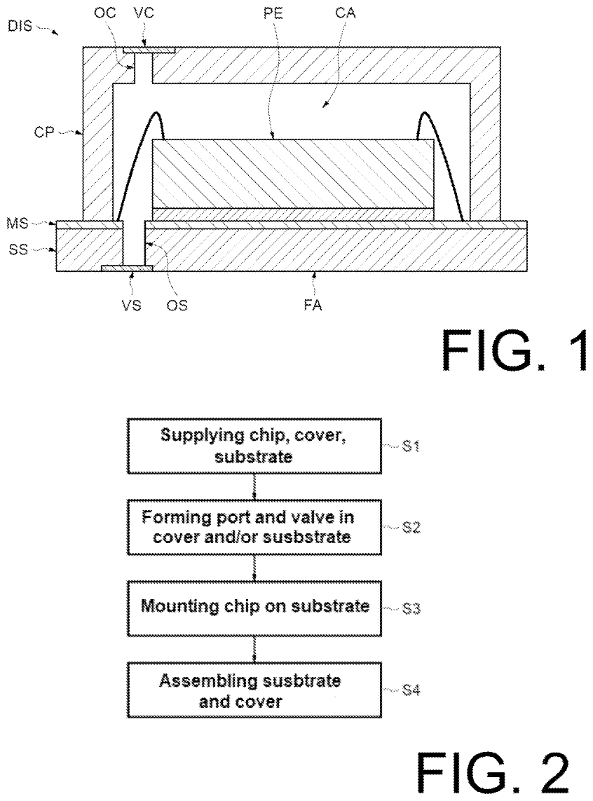

FIG. 1 illustrates an electronic device DIS comprising an electronic chip PE, a support substrate SS and a protection cover CP.

The substrate SS and the cover CP are assembled so as to form a cavity CA housing the chip PE.

The cavity CA is delimited by a concave chamber in the cover CP of which a rim is attached, for example bonded, on a solder resin layer MS covering the substrate SS.

Assembling the cover CP and the substrate SS makes it possible to mechanically protect fragile portions of the chip PE such as, for example, connection elements such as connecting wires or optical elements.

The resin layer MS covers the substrate SS such as to protect an interconnection network located at the surface of the substrate SS. The chip PE is, for example, electrically connected to the interconnection network by soldered wires.

The resin layer MS would be likely to crack at the layer caused by an overpressure in the cavity.

In order to avoid this, the cover CP and/or the substrate SS are produced such as to make it possible to evacuate overpressure gases from the inside of the cavity CA, to the outside of the cavity CA.

In particular, the cover CP, the substrate SS, or both the cover CP and the substrate SS, comprise one or more integrated ports OC, OS making it possible to make the cavity CA communicate with the outside.

In addition, in order to avoid the entry of pollutants in the cavity CA in the case of no overpressure, or even in the case of underpressure in the cavity CA, each port OC, OS is equipped with a unidirectional valve VC, VS. At rest (i.e., when closed), each valve VC, VS makes it possible to prevent the entry of pollutants in the cavity CA.

The unidirectional valves VC, VS protect the inside of the cavity CA from liquid and solid pollution, for example dust and fluids. Such pollution may, for example, come from a step of singulation of a wafer intended to form the support substrate SS.

Each valve VC, VS, comprises a fixed portion and a free portion.

The fixed portion of the valve VC, VS is integral with an outer face of the cover CP or of the substrate SS, respectively, at the edge of the port associated with the valve. For example, the valve VC, VS is located at an outer contour of the cover PC or a rear face FA of the substrate SS, respectively. The fixed portion may be, for example, bonded or integrated into the substrate SS or the cover CP.

The free portion of the valve VC, VS is located facing the port OC, OS such that at rest the free portion of the valve VC, VS seals the port. On the contrary, during an overpressure in the cavity CA the free portion lifts (to open the valve) and the port is cleared which makes it possible to evacuate the overpressure from the inside of the cavity CA to the outside of the cavity CA.

Each valve VC, VS may, for example, be formed integrally in a flexible material, an elastic return force of the flexible material making it possible to press the free portion of the valve VC, VS on the substrate SS or the cover CP at the edge of the port OC, OS.

The valve VC, VS is provided both so that at rest the free portion is firmly pressed against its port OS, OC such as to ensure the sealing of the cavity CA, whilst allowing the free portion to lift from its port when the pressure inside the cavity CA exceeds a certain threshold.

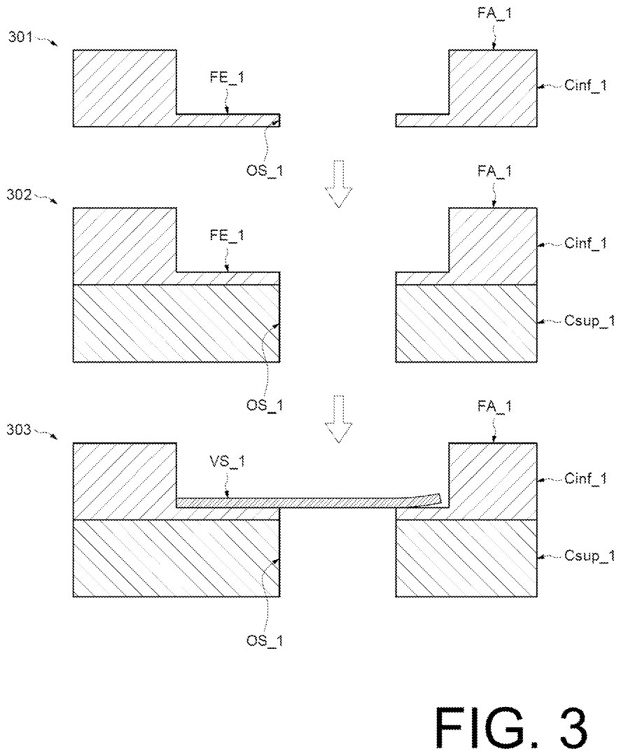

FIG. 2 illustrates a method for manufacturing the electronic device described in relation with FIG. 1.

The method illustrated comprises a step S1 of supplying a substrate, a cover and an electronic chip. Supplying means, for example, a delivery of products, a use of products coming from stocks or also a manufacturing of products.

In the example illustrated, the step S1 of supplying is followed by a step S2 of forming at least one port equipped with a unidirectional valve in the substrate and/or in the cover. The substrate and/or the cover is therefore reworked after the supplying.

Nevertheless, the order of steps S1 or S2 may be switched, or steps S1 and S2 may belong to a common manufacturing step. At least one port equipped with a valve may be produced in the substrate and/or the cover during the manufacture of the substrate and/or of the cover.

The order of steps S1 or S2 is, for example, switched when the substrate is manufactured directly such as to integrate at least one port equipped with a valve, as described further in relation with FIG. 4. This is, for example, also the case if the cover is molded such as to integrate at least one port equipped with a valve, as described further in relation with FIG. 5.

Furthermore, the method illustrated in FIG. 2 comprises a step S3 of mounting the electronic chip on the substrate, including an attachment of an anterior face of the electronic chip on the front face of the substrate, and also being able to comprise a connection of the chip to an interconnection network of the substrate.

After step S3 of mounting the chip on the substrate, the method comprises a step S4 of assembling the substrate and the cover such as to form the cavity housing the chip. Assembling the cover and the substrate comprises attaching the cover directly on the solder resin layer at the surface of the substrate.

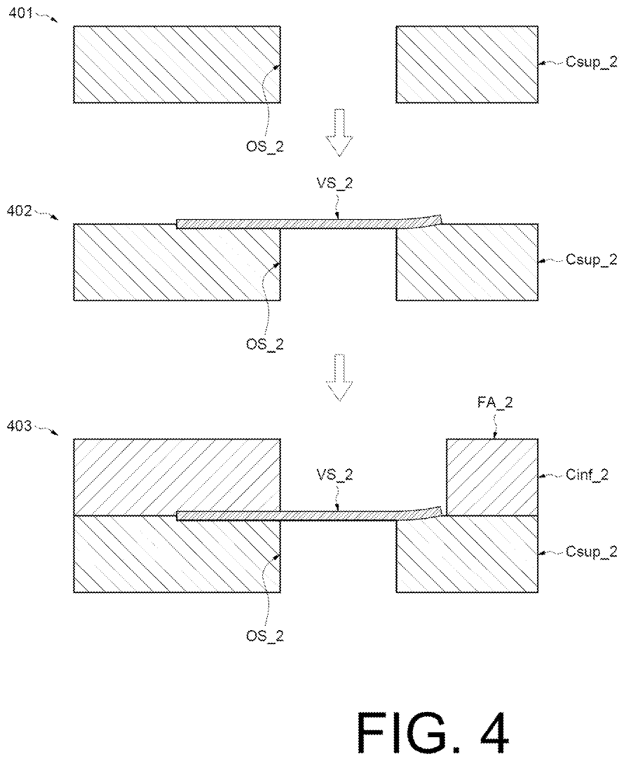

FIGS. 3, 4 and 5 illustrate steps of forming a port OS_1, OS_2, OC equipped with a valve VS_1, VS_2, VC in a substrate or in a cover CP.

FIGS. 3, 4 and 5 illustrate the formation of a single port equipped with one valve per figure. Nevertheless, of course, it is possible to form at the same time a plurality of ports equipped with respective valves, in the same substrate or in the same cover.

The substrates illustrated in FIGS. 3 and 4 comprise by way of example only two superposed dielectric layers, a lower layer Cinf_1, Cinf_2 and an upper layer Csup_1, Csup_2. Of course, according to needs, the substrate may comprise any number of superposed dielectric layers.

FIG. 3 illustrates steps 301, 302, 303 of a method leading to a formation of at least one port OS_1 equipped with a valve VS_1 in a support substrate, according to a first implementation.

This first implementation makes it possible to obtain a substrate comprising a port OS_1 wherein a fixed portion of the valve VS_1 is attached on an outer face FE_1 of the substrate. In this example, the valve VS_1 is located in a recess hollowed out in a rear face FA_1 of the substrate.

The recess is located at the edge of the port OS_1 and comprises the outer face FE_1.

The valve VA_1 is installed in the recess such that the fixed portion of the valve V1_1 is attached in the bottom of the recess. The bottom of the recess constitutes the outer face FE_1, substantially parallel to the rear face FA_1 and offset to the inside of the substrate, whereon the valve is attached. The free portion of the valve covers the port OS_1 and rests on a flange of the bottom of the recess.

The recess makes it possible to arrange a clearance space for the valve VA_1, such that the free portion of the valve VA_1 may lift without constraint even in a case where the rear face FA_1 of the substrate is pressed against a surface.

The formation of the port OS_1 comprises a step 301 including producing a first hole in the lower layer Cinf_1 and producing a second hole in the upper layer Csup_1.

The second hole forming the port OS_1 may be narrower than the first hole. The difference in width between the first and the second hole forms the recess in the rear face FA_1 intended to receive the valve VS_1.

The manufacture of the substrate comprises a step of assembling 302 the two superposed layers Cinf_1 and Csup_1 of the substrate. The superposed layers Cinf_1, Csup_1 of the substrate are, for example, layers of fiberglass mixed with epoxy resin that are, for example, assembled by compression and heating.

The formation of the port equipped with a valve comprises a step of attaching 303 the fixed portion of the valve VS-1, for example bonding the fixed portion on the outer face FE_1 of the substrate.

In this example, the port OS_1 is formed during the manufacture of the substrate.

Alternatively, it may be advantageous that the substrate is supplied already manufactured, then that the formation of the port OS_1 equipped with a valve VS_1 is performed after supplying the substrate, particularly for cost reasons.

According to this alternative, the method comprises supplying the substrate already manufactured, then forming the port OS_1 equipped with a valve, for example by piercing the substrate followed by attaching the fixed portion of the valve VS_1 on the substrate.

The formation of the port OS_1 may also comprise forming the recess, for example during the piercing of the port OS_1.

The attachment of the fixed portion of the valve is performed on the outer face FE_1 of the substrate at the edge of the port OS_1, for example by bonding.

FIG. 4 illustrates steps 401, 402, 403 of a method leading to a formation of a port OS_2 equipped with a valve VS_2 in a support substrate, according to a second implementation.

This second implementation makes it possible to obtain a substrate comprising a superposition of dielectric layers Cinf_2, Csup_2, wherein the port OS_2 is integrated into the substrate and wherein a fixed portion of the valve VS_2 is wedged between two of the superposed dielectric layers Cinf_2, Csup_2, of the substrate.

The formation of the port OS_1 comprises a step 401 including producing a first hole in the lower layer Cinf_2 and producing a second hole in the upper layer Csup_2, intended to form the port OS_2.

The widths of the holes are provided so that the free portion of the valve VS_2 rests, at rest, on a flange of the upper layer Csup_2 located set back in relation to a rear face of the support substrate.

Once the holes have been produced in the superposed layers, the manufacture of the substrate comprises assembling the lower layer Cinf_2 and the upper layer Csup_2 making it possible to wedge the fixed portion of the valve VS_2 between them.

Assembling the lower layer Cinf_2 and the upper layer Csup_2 comprises a step 402 of placing the fixed portion of the valve VS_2 on the upper layer Csup_2. The superposed layers Cinf_1, Csup_1 of the substrate are, for example, layers of fiberglass mixed with epoxy resin.

Assembling the lower layer Cinf_2 and the upper layer Csup_2 further comprises a step 403 of mutually connecting the layers including for example compression and heating.

FIG. 5 illustrates steps 501, 502 of a method leading to a formation of a port OC equipped with a valve VC in a protection cover CP.

This implementation makes it possible to obtain a port OC equipped with a valve VC of which a fixed portion is nested in the cover CP via branches RV.

The branches RV of the valve VC form a structure comprising hollowed portions and solid portions intended to retain the valve VC fixed portion in the cover CP.

The solid portions of the branches RV may, for example, comprise a grid, an arrangement of cells or lamellas arranged in the manner of a harpoon.

The branches RV and the free portion of the valve VC may be produced in the same flexible material, for example a plastic material of the rubber type.

The manufacture of the cover CP comprises a step 501 of molding material, for example epoxy resin.

The molding of the cover CP comprises use of a mold MO including an adhesive molding support making it possible to position the valve VC on the mold MO before the molding and holding in position during the molding.

The molding of the cover CP also comprises the formation of the port OC.

The formation of the port comprises use of an impression having an outer contour making it possible to form the walls of the port OC. The impression may, for example, form part of the mold MO.

The use of the impression may also comprise producing a recess in the cover CP intended to create a free space permitting clearances at the free portion of the valve VC.

The molding further comprises nesting the branches RV of the valve VC in the cover CP via creeping of the molded material in the hollowed portions of the branches RV.

Once the material of the cover has solidified, the molding is followed by a mold removal step 502, the branches RV of the valve VC are then integral with the cover CP.

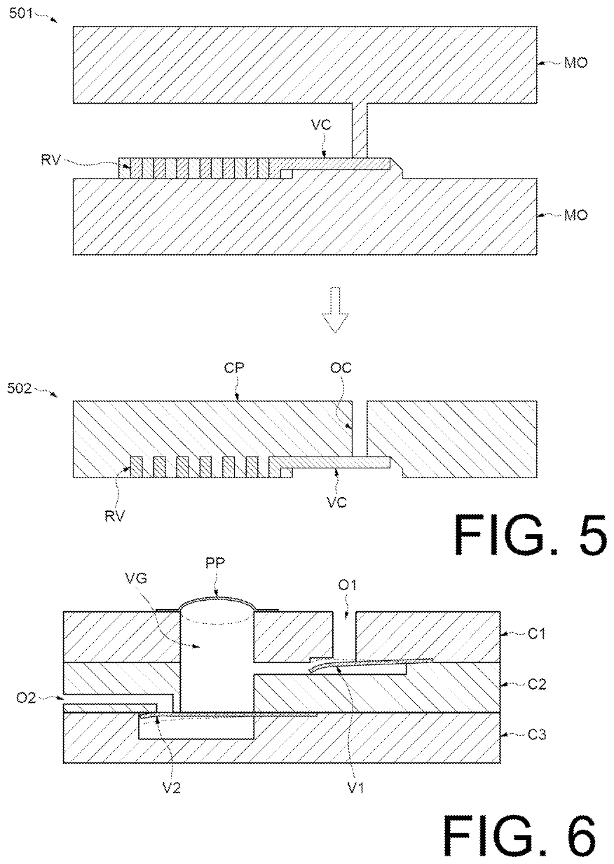

FIG. 6 illustrates an alternative pumping system adapted for the circulation of a fluid, such as a liquid or a gas, combining the previously described valves, in particular in relation with FIG. 4, and a piezoelectric membrane PP.

The pumping system is produced in a support substrate SS. The support substrate SS comprises a first dielectric layer C1, a second dielectric layer C2, and a third dielectric layer C3 superposed.

The pumping chamber VG is formed by a first through hole in the first layer C1, a second through hole in the second layer C2 and a non-through material recess in the third layer C3.

The first hole, the second hole and the recess are aligned in such a way as to delimit the volume of the pumping chamber VG.

The pumping chamber VG comprises a piezoelectric membrane PP that is disposed such as to close the pumping chamber VG by covering the first hole of the first layer C1.

The piezoelectric membrane PP is provided in order to modify the volume of the pumping chamber VG according to a voltage applied.

The pumping chamber VG comprises an inlet port O1 and an outlet port O2 to allow the circulation of fluid or of gas.

The inlet port O1 is equipped with a unidirectional inlet valve V1 and the outlet port O2 is equipped with a unidirectional outlet valve V2.

The inlet valve V1 is provided to allow the unidirectional circulation of fluid to the inside of the pumping chamber VG. The outlet valve V2 is provided to allow the unidirectional circulation of fluid to the outside of the pumping chamber VG.

A fixed portion of the inlet valve V1 is wedged between the first layer C1 and the second layer C2, a fixed portion of the outlet valve V2 is wedged between the second C2 and the third layer C3.

Alternatively, it is also possible to attach the fixed portions of the inlet valve V1 and of the outlet valve V2 such as previously described in relation with FIG. 4.

According to this alternative, the inlet valve V1 is attached in a first recess located at the edge of the inlet port O1 in the first layer C1, and the outlet valve V2 is attached in a second recess located at the edge of the outlet port O2 in the second layer C2.

The operation of the pumping system comprises two phases that repeat cyclically in order to make a fluid circulate between the inlet port O1 and the outlet port O2 of the chamber VG.

In a first phase, the piezoelectric membrane PP deforms in a first position such as to increase the volume of the chamber VG in order to draw the fluid via the inlet port O1. During the first phase, the inlet valve V1 is opened and the outlet valve V2 is pressed against the outlet port O2.

In a second phase (the positions of which are shown in dotted lines), the piezoelectric membrane PP deforms in a second position such as to reduce the volume of the chamber VG in order to evacuate, via the outlet port O2, the fluid drawn during the first phase. During the second phase, the inlet valve V1 is pressed against the inlet port O1 and the outlet valve V2 is opened.

The alternation of the first phase and of the second phase makes it possible to move gas or fluid from the inlet port O1 to the outlet port O2.

The pumping system may be adapted to cool a substrate where a chip is mounted. A coolant may, for example, circulate in the substrate, under the chip, such as to transport the thermal energy generated by the chip during its operation, particularly by Joule effect.

1. An electronic device, comprising:
an electronic chip;
a support substrate;
a protection cover;
wherein the support substrate and the protection cover are assembled so as to form a cavity housing the electronic chip; and
a port equipped with a unidirectional valve being provided in one of the support substrate or the protection cover, said unidirectional valve configured to evacuate gas from inside the cavity to outside of the cavity.

2. The device according to claim 1, wherein said port is integrated into the support substrate and wherein said unidirectional valve comprises a fixed portion bonded on an outer face of the substrate at a location at an edge of said port and a free portion extending from the fixed portion to cover an opening of said port.

3. The device according to claim 2, wherein said unidirectional valve is formed integrally in a flexible material with the free portion facing the opening of the port and configured to seal the opening by an elastic return force.

4. The device according to claim 1, wherein said port is integrated into the support substrate, said support substrate comprising a superposition of dielectric layers, and wherein said unidirectional valve comprises a fixed portion wedged between two of the dielectric layers and a free portion extending from the fixed portion to cover an opening of said port.

5. The device according to claim 4, wherein said unidirectional valve is formed integrally in a flexible material with the free portion facing the opening of the port and configured to seal the opening by an elastic return force.

6. The device according to claim 1, wherein said port is integrated into the protection cover, and said unidirectional valve comprises a fixed portion including branches nested in the protection cover and a free portion extending from the fixed portion to cover an opening of said port.

7. The device according to claim 6, wherein said unidirectional valve is formed integrally in a flexible material with the free portion facing the opening of the port and configured to seal the opening by an elastic return force.

8. The device according to claim 1, wherein said unidirectional valve is formed integrally in a flexible material and includes a fixed portion integral with an outer face of one of the support substrate or the protection cover at an edge of the port and a free portion facing the port and configured to seal the port by an elastic return force pressing on said outer face.

9. The device according to claim 1, wherein said unidirectional valve is formed integrally in a flexible material and includes a fixed portion that is wedged between layers of one of the support substrate or the protection cover at an edge of the port and a free portion facing the port and configured to seal the port by an elastic return force.

10. A method for manufacturing an electronic device, comprising:
supplying an electronic chip, a support substrate and a cover;
forming, in one of the support substrate or the protection cover, a port equipped with a unidirectional valve;
mounting the electronic chip to the support substrate; and
assembling the support substrate and the protection cover to form a cavity housing the electronic chip, wherein said port equipped with said unidirectional valve is configured to evacuate gas from inside of the cavity to outside of the cavity.

11. The method according to claim 10, wherein forming the port equipped with the unidirectional valve comprises, after supplying the substrate, bonding a fixed portion of said unidirectional valve on an outer face of the support substrate at an edge of said port with a free portion extending from the fixed portion to cover an opening of said port.

12. The method according to claim 10, wherein forming the port equipped with the unidirectional valve is performed at manufacture of the support substrate and comprises, prior to supplying the support substrate, bonding two dielectric layers belonging to a superposition of dielectric layers and wedging a fixed portion of said unidirectional valve between said two dielectric layers with a free portion extending from the fixed portion to cover an opening of said port.

13. The method according to claim 10, wherein forming the port equipped with the unidirectional valve is performed at manufacture of the protective cover and comprises, prior to supplying the protection cover, molding the protective cover by nesting in the protective cover a plurality of branches forming a fixed portion of said unidirectional valve with a free portion extending from the fixed portion to cover an opening of said port.

14. The method according to claim 10, wherein forming the equipped with the unidirectional valve comprises forming the unidirectional valve integrally in a flexible material, securing a fixed portion of the unidirectional valve on an outer face of one of the support substrate or the protection cover at an edge of the port, and positioning a free portion of the unidirectional valve facing the port and configured to seal the port by an elastic return force pressing on said outer face.

15. The method according to claim 10, wherein forming the equipped with the unidirectional valve comprises forming the unidirectional valve integrally in a flexible material, securing a fixed portion of the unidirectional valve wedged between layer of one of the support substrate or the protection cover at an edge of the port, and positioning a free portion of the unidirectional valve facing the port and configured to seal the port by an elastic return force.

16. A system, comprising:
a support substrate including a stack of a first dielectric layer, a second dielectric layer and a third dielectric layer;
wherein the support substrate includes a first through hole in the first dielectric layer, a second through hole in the second dielectric layer and a recess in the third dielectric layer;
wherein the support substrate further a pumping chamber extending through the first and second dielectric layers in alignment with the recess;
a piezoelectric membrane disposed on the first dielectric layer to close the pumping chamber;
a first unidirectional valve positioned between the first through hole and the pumping chamber;
a second unidirectional valve positioned between the pumping chamber and the recess and further positioned between the recess and the second through hole;
wherein the piezoelectric membrane has a first position which closes the second unidirectional valve and opens the first unidirectional value and further has a second position which opens the second unidirectional valve and closes the first unidirectional value.

17. The system of claim 16, wherein a fixed portion of said first unidirectional valve is wedged between the first and second dielectric layers.

18. The system of claim 16, wherein a fixed portion of said second unidirectional valve is wedged between the second and third dielectric layers
